(19) United States
(12) Patent Application Publication
(10) Pub. No.: US 2025/0008758 A1
(43) Pub. Date: Jan. 2, 2025

(54) DETECTION SUBSTRATE AND DETECTION DEVICE

(71) Applicants: Beijing BOE Optoelectronics Technology Co., Ltd., Beijing (CN); BOE Technology Group Co., Ltd., Beijing (CN)

(72) Inventors: Dexi KONG, Beijing (CN); Lin ZHOU, Beijing (CN); Cheng LI, Beijing (CN); Tiansheng LI, Beijing (CN); Ziran LIU, Beijing (CN); Shoujin CAI, Beijing (CN); Jin CHENG, Beijing (CN); Jie ZHANG, Beijing (CN); Gen HUANG, Beijing (CN); Zixiao CHEN, Beijing (CN)

(21) Appl. No.: 18/709,640

(22) PCT Filed: Nov. 19, 2021
(86) PCT No.: PCT/CN2021/131944

§ 371 Date: May 13, 2024

(51) Int. Cl. H10K 39/38; H10K 39/32

(52) U.S. Cl. CPC H10K 39/38; H10K 39/32

(57) ABSTRACT

The disclosure provides a detection substrate and a detection device. The detection substrate includes: a base substrate including a photosensitive area and a peripheral area surrounding the photosensitive area; a plurality of organic photodetectors on the base substrate which are arranged in an array in the photosensitive area, the organic photodetectors each including a first electrode, an organic photoelectric detection function layer, and a second electrode which are stacked, and the second electrodes of all organic photodetectors being integrally arranged and extending from the photosensitive area to the peripheral area; and a bias line, the bias line being a strip-shaped line extending in a first direction in the peripheral area, the bias line being electrically connected to the second electrodes in the peripheral area, and the minimum distance between the bias line and the organic photoelectric detection function layers in the second direction is greater than a preset threshold.

### CROSS REFERENCE TO RELATED APPLICATIONS

This application is a national phase entry under 35 U.S.C. § 371 of International Application No. PCT/CN2021/131944, filed on Nov. 19, 2021, the entire content of which is incorporated herein by reference.

### TECHNICAL FIELD

The disclosure relates to the technical field of photoelectric detection, in particular to a detection substrate and a detection device.

### BACKGROUND

With the rapid development of communication, network, and financial technology, information security has shown unprecedented importance, and the application of human identification technology has become more and more extensive. Biometric technology refers to the science and technology that uses physiological characteristics (such as face, fingerprint, finger vein) or behavioral characteristics to automatically identify individuals. The finger vein recognition technology uses near-infrared rays to penetrate fingers to obtain finger vein patterns for identity recognition. It is the world's most cutting-edge biometric technology with high precision and high speed. Among various biotechnologies, the finger vein recognition technology is attracting attention as a highly counterfeit-proof biotechnology using internal features that are not visible from the outside. It has a very broad application prospect in many aspects of the security field. The finger vein automatic identification system has been successfully applied in identity fraud prevention, security, education, finance, government and enterprise, and consumer products. Therefore, the finger vein sensor has broad application prospects.

Compared with other biometric technologies, the finger vein recognition technology allows non-contact measurement, which is hygienic and easy to be accepted by users. It is internal information of the human body that is recognized, so that the measurement is not affected by rough skin and external environment (humidity, temperature), which is applicable to a wider range of users, and has effects of high accuracy, non-replicable, non-forgeable. The disadvantage of the existing finger vein recognition technology is that the product is difficult to miniaturize due to the collection method being limited by its own characteristics: the collection area and the thickness of the module are mutually restricted, the larger the collection area is, the thicker the module is; the collection equipment has special requirements and is relatively complicated to design and expensive to manufacture. While the ultra-thin finger vein recognition solution can realize large-area detection with an ultra-thin and flexible structure, overcoming the deficiencies of traditional finger vein recognition.

### SUMMARY

The detection substrate and the detection device provided by the embodiments of the disclosure have specific solutions as follows.

In one aspect, an embodiment of the disclosure provides a detection substrate, including: a base substrate including a photosensitive area, and a peripheral area surrounding the photosensitive area; a plurality of organic photodetectors on the base substrate, where the plurality of organic photodetectors are arranged in an array in the photosensitive area, and each of the organic photodetectors includes a first electrode, an organic photodetection function layer and a second electrode which are arranged in a stack manner, and second electrodes of all the organic photodetectors are integrated and extend from the photosensitive area to the peripheral area; and a bias line which is a strip-shaped line extending along a first direction in the peripheral area, where the bias line is electrically connected with the second electrodes in the peripheral area; a minimum distance between the bias line and the organic photodetection function layer in a second direction is greater than a preset threshold, and the first direction and the second direction are perpendicular to each other, and the first direction and the second direction are both parallel to the base substrate.

In some embodiments, the peripheral area includes a first peripheral area and a second peripheral area, where the first peripheral area is configured to bond a gate driver chip, and the second peripheral area is opposite to the first peripheral area. Integrated second electrodes extend from the photosensitive area to the second peripheral area, and the bias line is located in the second peripheral area.

In some embodiments, an orthographic projection of a boundary of the bias line at a side away from the photosensitive area on the base substrate is approximately coincident with an orthographic projection of a boundary of the second electrode on the base substrate.

In some embodiments, the bias line includes a first bias portion; the first bias portion and the first electrode are arranged in a same layer and of same material, and the first bias portion is in direct contact with the second electrodes.

In some embodiment, the bias line further includes a second bias portion, the second bias portion is located between a layer where the first electrode is and the base substrate, and the second bias portion is electrically connected with the first bias portion.

In some embodiments, the detection substrate further includes a first insulating layer, the first insulating layer is located between the layer where the first electrode is and the base substrate. The first insulating layer includes a first via hole, and an orthographic projection of the first via hole on the base substrate is located within an orthographic projection of the bias line on the base substrate. The first bias portion and the second bias portion are electrically connected through the first via hole.

In some embodiments, the detection substrate further includes: a pixel driving circuit and a second insulating layer. The pixel driving circuit is located between a layer where the second bias portion is and the base substrate, the second insulating layer is located between the layer where the second bias portion is and a layer where the pixel driving circuit is. The first insulating layer and the second insulating layer includes a second via hole passing through the first insulating layer and the second insulating layer, and an orthographic projection of the second via hole on the substrate is located within an orthographic projection of the organic photodetector on the base substrate. The pixel driving circuit is electrically connected with the organic photodetector through the second via hole.

In some embodiments, the bias line includes a plurality of first sub-bias lines and a plurality of second sub-bias lines, the plurality of first sub-bias lines and the plurality of second sub-bias lines are arranged in a same layer and intersect with each other, where the first sub-bias lines extend along the first direction, and the second sub-bias lines extend along the second direction.

In some embodiments, a line width of the first sub-bias lines is smaller than a line width of the second sub-bias lines.

In some embodiments, the second sub-bias line includes at least one hollow pattern, and an orthographic projection of the hollow pattern on the base substrate and orthographic projections of the first sub-bias lines on the base substrate do not overlap each other.

In some embodiments, a length of the second sub-bias line in the second direction is greater than or equal to 650 μm and less than or equal to 850 μm.

In some embodiments, the minimum distance between the bias line and the organic photodetection function layer in the second direction is greater than or equal to 500 μm and less than or equal to 600 μm.

In some embodiments, the detection substrate further includes a static electricity line, a plurality of electrostatic discharge circuits, and a plurality of gate lines located in the peripheral area. The static electricity line, the plurality of electrostatic discharge circuits, and the plurality of gate lines are all located between the organic photodetection function layer and the base substrate, and the electrostatic wiring is electrically connected with the gate lines through the electrostatic discharge circuits.

In some embodiments, the electrostatic discharge circuits are electrically connected with the gate lines in a one-to-one correspondence.

In some embodiments, the electrostatic discharge circuit includes a first transistor and a second transistor. A gate of the first transistor is electrically connected with the gate line, a first electrode of the first transistor is electrically connected with the gate of the first transistor, and a second electrode of the first transistor is electrically connected with a first electrode of the second transistor. A gate of the second transistor is electrically connected with the static electricity line, the first electrode of the second transistor is electrically connected with the gate of the second transistor, and the second electrode of the second transistor is electrically connected with the first electrode of the first transistor.

In some embodiments, the detection substrate further includes a plurality of bridge lines, a layer where the bridge lines are is located between the layer where the first electrode is and the base substrate. A part of the bridge lines connect the gate of the first transistor and the first electrode of the first transistor, and a rest of the bridge lines connect the gate of the second transistor, the first electrode of the second transistor and the static electricity line.

In some embodiments, the detection substrate further includes a plurality of light-shielding elements located in the peripheral area, and a layer where the plurality of light-shielding elements are is located between the organic photodetection function layer and the base substrate. Orthographic projections of the plurality of light-shielding elements on the base substrate overlap with an orthographic projection of an active layer of each of the first transistors on the base substrate, and an orthographic projection of an active layer of each of the second transistors on the base substrate.

In some embodiments, the first electrode includes a metal part, and the plurality of light-shielding elements and the metal part are arranged in a same layer, and of same material.

In some embodiments, the first electrode further includes a transparent conductive part, the transparent conductive part is located on a side of the metal part away from the base substrate, and the transparent conductive part is in direct contact with the metal part.

In some embodiments, the peripheral area further includes a third peripheral area, and the third peripheral area connects the first peripheral area and the second peripheral area. The plurality of gate lines are located in the photosensitive area. The static electricity line is located in the first peripheral area, the second peripheral area, and the third peripheral area, and the static electricity line in the second peripheral area is located between the bias line and the photosensitive area. The plurality of electrostatic discharge circuits are located in the first peripheral area and the second peripheral area, and the plurality of electrostatic discharge circuits are located between the static electricity line and the photosensitive area.

In some embodiments, the gate driving chip is located on a side of the electrostatic wiring away from the photosensitive area, and the gate driving chip is electrically connected with the gate lines.

In some embodiments, the peripheral area further includes a fourth peripheral area, and the fourth peripheral area is opposite to the third peripheral area. The detection substrate further includes a readout chip, the readout chip is bonded onto the fourth peripheral area, and the readout chip is electrically connected with the bias line.

In another aspect, an embodiment of the disclosure provides a detection device, including a light source and a detection substrate, where the detection substrate is the above-mentioned detection substrate provided by the embodiment of the disclosure.

### BRIEF DESCRIPTION OF FIGURES

FIG. 1 is a schematic structural diagram of a detection substrate in the related art.

FIG. 2 is a schematic top view of a detection substrate provided by embodiments of the disclosure.

FIG. 3 is a schematic diagram of a cross-sectional view of a detection substrate provided by embodiments of the disclosure.

FIG. 4 is a schematic diagram of another cross-sectional view of a detection substrate provided by embodiments of the disclosure.

FIG. 5 is a schematic diagram of an enlarged view of the Z2 area in FIG. 2.

FIG. 6 is a schematic diagram of the enlarged view of the Z1 area in FIG. 1.

FIG. 7 is a schematic diagram of the enlarged view of the Z3 area in FIG. 2.

FIG. 8 is a schematic diagram of another cross-sectional view of a detection substrate provided by embodiments of the disclosure.

FIG. 9 is a schematic diagram of another cross-sectional view of a detection substrate provided by embodiments of the disclosure.

FIG. 10 is a schematic structural diagram of a detection device provided by embodiments of the disclosure.

### DETAILED DESCRIPTION

In order to make the purpose, technical solutions and advantages of the embodiments of the disclosure clearer, the technical solutions of the embodiments of the disclosure will be clearly and completely described below in conjunction with the accompanying drawings of the embodiments of the disclosure. It should be noted that the size and shape of each figure in the drawings do not reflect the true scale, but are only intended to illustrate the disclosure. And the same or similar reference numerals indicate the same or similar elements or elements having the same or similar functions throughout.

Unless otherwise indicated, the technical terms or scientific terms used herein shall have the usual meanings understood by those having ordinary skill in the art to which the disclosure belongs. “First”, “second” and similar words used in the disclosure and claims do not indicate any order, quantity or importance, but are only used to distinguish different components. “Comprising” or “including” and similar words mean that the elements or items appearing before the word include the elements or items listed after the word and their equivalents, without excluding other elements or items. “Inner”, “outer”, “upper”, “lower” and so on are only used to indicate relative positional relationship. When the absolute position of the described object changes, the relative positional relationship may also change accordingly.

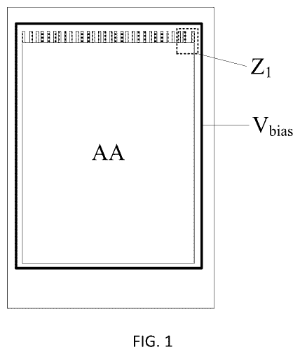

FIG. 1 shows a detection substrate in the related art, which is provided with a ring bias line (Vbias) around the photosensitive area AA. The bias line is electrically connected with the top electrode of the organic photodetector (OPD) in the photosensitive area AA, so as to provide a bias voltage to the top electrode through the bias line. However, since the bias line is very close (about 100 μm) to the photosensitive area AA, and the line width of the bias line is narrow (about 308 μm), when the organic photodetection function layer of the organic photodetector is formed subsequently, the organic photodetection function layer is easy to cover the bias line, resulting in an open circuit between the bias line and the top electrode or a short circuit between the bias line and the organic photodetection function layer, so that the organic photodetector cannot work normally (NG).

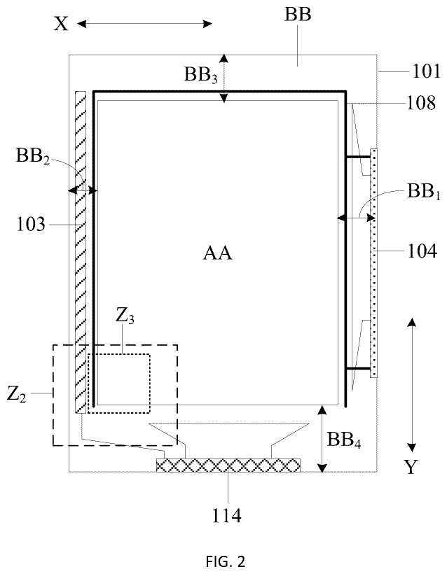

In order to solve the above-mentioned technical problems existing in related art, an embodiment of the disclosure provides a detection substrate, as shown in FIG. 2 to FIG. 5, including:
a base substrate 101 including a photosensitive area AA, and a peripheral area BB surrounding the photosensitive area AA;
a plurality of organic photodetectors 102 located on the base substrate 101; the plurality of organic photodetectors 102 are arranged in an array in the photosensitive area AA, and each of the organic photodetectors 102 includes a first electrode 1021, an organic photodetection function layer 1022 and a second electrode 1023 disposed in a stack manner, where the second electrodes 1023 of all organic photodetectors 102 are integrally arranged and extend from the photosensitive area AA to the peripheral area BB. Optionally, the organic photodetection function layer 1022 may include an electron transport layer (ETL) 221, an organic photodetection material layer (Active) 222 and a hole transport layer (HTL) 223, where the material of the organic photodetection material layer 222 can be organic photoelectric materials, such as a bulk heterojunction formed by combining SPV-001 and PCBM, a bulk heterojunction formed by the combination of PMDPP3T and PC61BM, etc;
a bias line 103, where the bias line 103 is a strip-shaped line extending along a first direction Y in the peripheral area BB, and is electrically connected with the second electrodes 1023 in the peripheral area BB. Optionally, the second electrodes 1023 extend from the photosensitive area AA to the peripheral area BB where the bias line 103 is located, and cover the bias line 103 to realize the electrical connection between the second electrodes 1023 and the bias line 103; a minimum distance d between the bias line 103 and the organic photodetection function layer 1022 (that is, the distance between the bias voltage line 103 and the organic photodetection function layer 1022 contained in the outermost of organic photodetector 102) in the second direction X is greater than a preset threshold value. In some embodiments, the preset threshold value can be an etching deviation of the organic photodetection function layer 1022 (i.e. a difference between the design value and the actual value of the organic photodetection function layer 1022). The etching deviation is related to factors such as the material and the etching process of the organic photodetection function layer 1022. For example, the etching deviation can be greater than or equal to 100 μm and less than or equal to 300 μm. Optionally, in the second direction X, the minimum distance d from the bias voltage line 103 to the organic photodetection function layer 1022 can be greater than or equal to 500 μm and less than or equal to equal to 600 μm, for example, d is 550 μm. Here, the first direction Y and the second direction X are perpendicular to each other, and both the first direction Y and the second direction X are parallel to the base substrate 101.

In the above detection substrate provided by the embodiments of the disclosure, by setting the minimum distance d from the bias voltage line 103 to the organic photodetection function layer 1022 to be greater than the etching deviation of the organic photodetection function layer 1022, the organic photodetection function layer 1022 can be prevented from covering the bias line 103, so there will be no short circuit between the bias line 103 and the organic photodetection function layer 1022, and meanwhile, it can be guaranteed that the bias line 103 can be directly covered by the second electrode 1023 and directly in contact with the second electrode 1023 to electrically connected with the second electrode 1023, thereby realizing the normal operation of the organic photodetector 102.

In some embodiments, in the detection substrate provided by the embodiments of the disclosure, as shown in FIG. 2, the peripheral area BB may include a first peripheral area BB1 and a second peripheral area BB2, where the first peripheral area BB1 is used for bonding the gate driver chip (Gate COF) 104, the second peripheral area BB2 is opposite to the first peripheral area BB1. The integrated second electrode 1023 extends from the photosensitive area AA to the second peripheral area BB2, and the bias line 103 is located within the second peripheral zone BB2. Since the minimum distance d from the bias line 103 to the organic photodetection function layer 1022 is relatively large in the disclosure, it is necessary to have enough space for the bias line 103 in the peripheral area BB. By arranging the bias line 103 in the second peripheral area BB2 opposite to the gate driver chip 104, there is enough space to keep the bias line 103 away from the photosensitive area AA, and avoid a poor short circuit between the bias line 103 and the gate driver chip 104 caused by the bias line 103 and the gate driver chip 104 being co-located in the first peripheral area BB1.

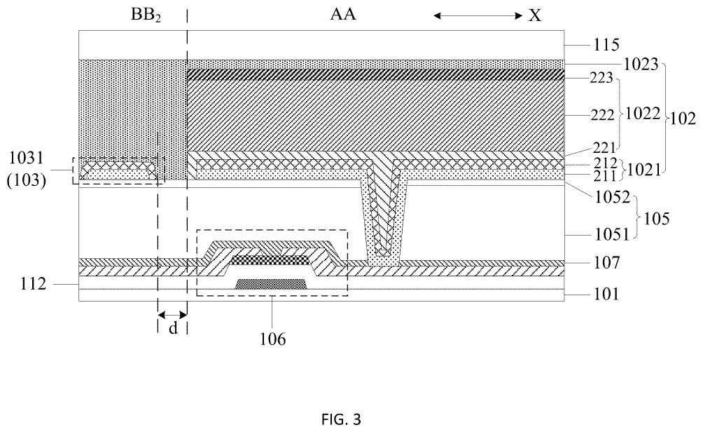

In some embodiments, in the above detection substrate provided by the embodiments of the disclosure, as shown in FIG. 3, an orthographic projection of a boundary of the bias line 103 away from the photosensitive area AA on the base substrate 101 is roughly coincident with an orthographic projection of a boundary of the second electrode 1023 on the base substrate 101, so as to reduce the square resistance of the bias line 103. Optionally, the material of the second electrode 1023 can be a transparent conductive material such as indium tin oxide (ITO).

It should be noted that, in the embodiments provided in the disclosure, due to the limitation of process conditions or the influence of other factors such as measurement, the “approximate coincidence” may coincide exactly, and there may also be some deviations (for example, a deviation of +10 μm), so the relationship of “substantially coincident” between related features falls within the scope of protection of the disclosure as long as the error tolerance is satisfied.

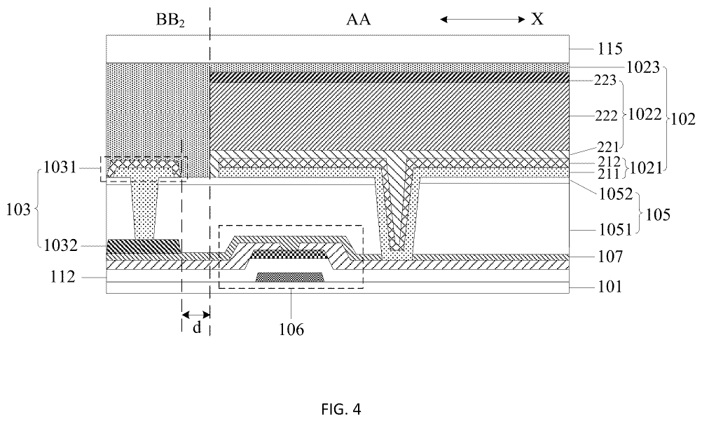

In some embodiments, in the detection substrate provided by the embodiments of the disclosure, as shown in FIG. 3 and FIG. 4, the bias line 103 may include a first bias portion 1031. The first bias portion 1031 and the first electrode 1021 are in a same layer and of the same material. The first bias portion 1031 is in direct contact with the second electrode 1023. In the disclosure, “same layer” refers to a layer structure formed by using a same film forming process to form a film layer for making a specific pattern, and then using a patterning process via a same mask. That is, one patterning process corresponds to one mask (also called a photomask). According to different specific patterns, a patterning process may include multiple exposure, development or etching processes, and the specific patterns in the formed layer structure may be continuous or discontinuous, and these specific patterns may be at the same height or have the same thickness, may also be at different heights or have different thicknesses. Therefore, the first bias portion 1031 and the first electrode 1021 are arranged in the same layer and of the same material, which can reduce the number of mask numbers, improve production efficiency, and reduce production costs.

Optionally, as shown in FIG. 3 and FIG. 4, the first electrode 1021 may be a double-layer structure including the metal part 211 and the transparent conductive part 212, and the transparent conductive part 212 is located on a side of the metal part 211 away from the base substrate 101, and in direct contact with the organic photodetection function layer 1022. Correspondingly, the first bias portion 1031 disposed in the same layer as the first electrode 1021 also has a double-layer structure formed of metal and transparent conductive material. For this, the second electrode 1023 can effectively prevent water vapor from corroding the metal in the bias line 103.

In some embodiments, in the above detection substrate provided by the embodiments of the disclosure, as shown in FIG. 4, the bias line 103 may further include a second bias portion 1032, and the second bias portion 1032 is located between a layer where the first electrode 1021 is, and the base substrate 101, and the second bias portion 1032 is electrically connected with the first bias portion 1031, so as to further reduce the square resistance of the bias line 103. Optionally, the material of the second biasing portion 1032 may be titanium, aluminum, molybdenum and other metals.

In some embodiments, the detection substrate provided by the embodiment of the disclosure, as shown in FIG. 4, may further include a first insulating layer 105. The first insulating layer 105 is located between the layer where the first electrode 1021 is and the base substrate 101. The first insulating layer 105 includes a first via hole, and the orthographic projection of the first via hole on the base substrate 101 is within the orthographic projection of the bias line 103 on the base substrate 101. The first bias portion 1031 is electrically connected with the second bias portion 1032 through the first via hole. Optionally, the first insulating layer 105 may include a planarization layer 1051 and an inorganic insulating layer 1052 located between the planarization layer 1051 and the layer where the first electrode 1021 is.

In some embodiments, the detection substrate provided by the embodiments of the disclosure, as shown in FIG. 4, may further include a pixel driving circuit 106 and a second insulating layer 107. The pixel driving circuit 106 is located between the layer where the second bias portion 1032 is and the base substrate 101, the second insulating layer 107 is between the layer where the second bias portion 1032 is and the layer where the pixel driving circuit 106 is. The first insulating layer 105 and the second insulating layer 107 include a second via hole passing through the first insulating layer 105 and the second insulating layer 107. The orthographic projection of the second via hole on the base substrate 101 is within the orthographic projection of the organic photodetector 102 on the base substrate 101. The pixel drive circuit 106 is electrically connected with the organic photodetector 102 through the second via hole. The pixel driving circuit 106 can be of an active mode (APS) or a passive mode (PPS), which is not limited here.

In some embodiments, in the detection substrate provided by the embodiments of the disclosure, as shown in FIG. 5, the bias line 103 may include a plurality of first sub-bias lines V1 and a plurality of second sub-bias lines V2 which are arranged at the same layer and intersect with each other, where the first sub-bias lines V1 extend along the first direction Y, and the second sub-bias lines V1 extend along the second direction X. The intersected plurality of first sub-bias lines V1 and the plurality of second sub-bias line V2 define a plurality of grids, which can greatly reduce the square resistance of the bias line 103.

In some embodiments, in the detection substrate provided by the embodiments of the disclosure, as shown in FIG. 5, the line width of the first sub-bias line V1 is smaller than the line width of the second sub-bias line V2, so that the intersection area of the first sub-bias line V1 and the second sub-bias line V2 is relatively large, which reduces the risk of disconnection.

In some embodiments, in the above detection substrate provided by the embodiments of the disclosure, as shown in FIG. 5, the second sub-bias line(s) V2 may include at least one hollow pattern K. The orthographic projection of the hollow pattern K on the base substrate 101 and the orthographic projections of the first sub-bias lines V1 on the base substrate 101 do not overlap with each other. Such arrangement, on the one hand, can ensure that the first sub-bias lines V1 and the second sub-bias lines V2 can still intersect to avoid disconnection; on the other hand, it can further reduce the square resistance of the bias line 103, which is beneficial to the bias signal transmission.

In some embodiments, in the detection substrate provided by the embodiments of the disclosure, as shown in FIG. 5, in order to increase the contact yield between the bias lines 103 and the second electrode 1023, the length L of the second sub-bias lines V2 in the second direction X (corresponding to the length of the bias line 103 in the second direction X) may be greater than or equal to 650 μm and less than or equal to 850 μm, for example, may be 750 μm.

In some embodiments, as shown in FIG. 5, the outermost organic photodetectors 102 in the photosensitive area AA can be used as dummy pixels (DPs), and the organic photodetectors 102 inside the photosensitive area AA (i.e. the organic photodetectors 102 surrounded by DPs) are used for the finger vein recognition.

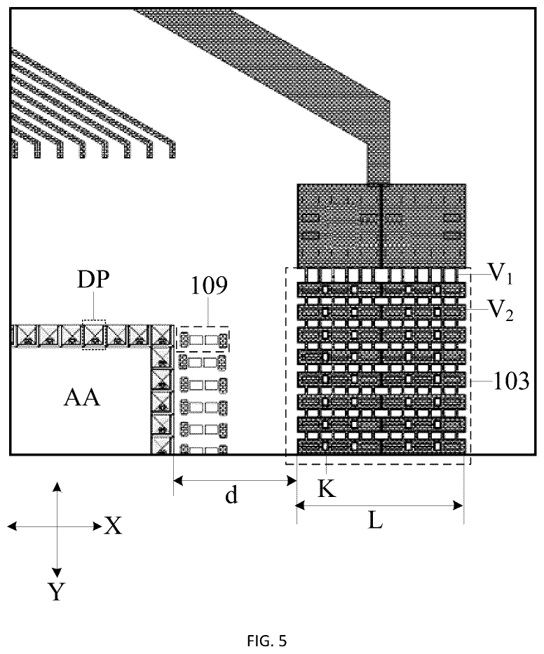

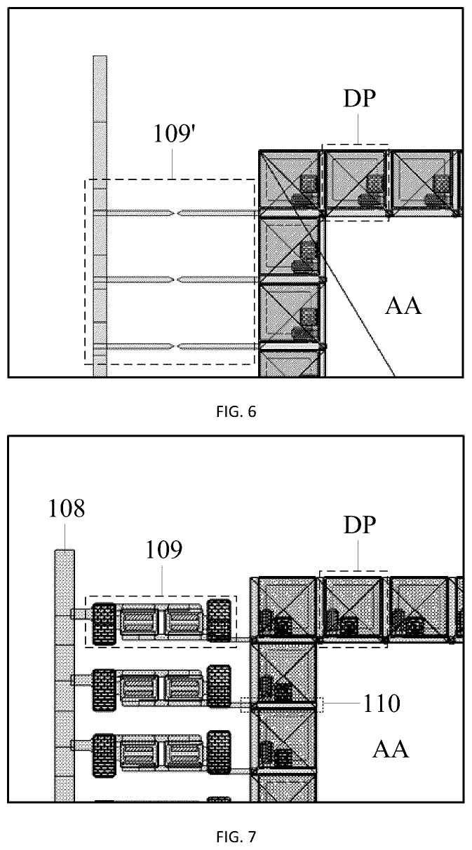

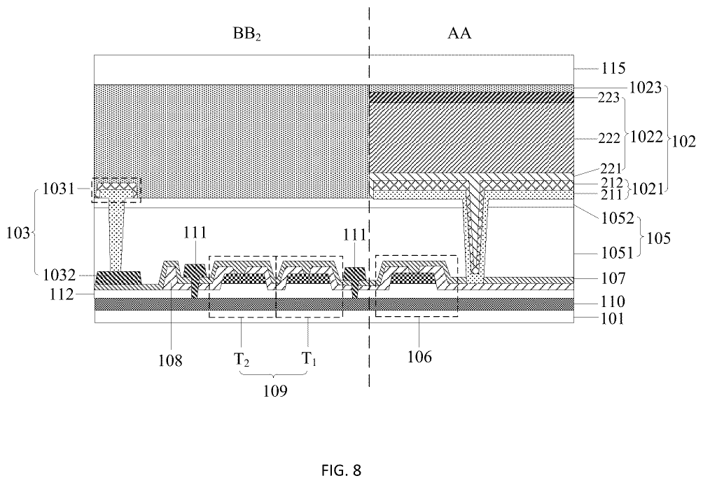

As shown in FIG. 1 and FIG. 6, in the related art, the tip 109′ discharge solution is used to avoid the interference of Electro-Static discharge (ESD) on the scanning signal of the gate line, however, the antistatic performance is relatively poor. Based on this, in order to improve the antistatic performance, as shown in FIG. 7 and FIG. 8, the detection substrate provided by the embodiments of the disclosure may further includes a static electricity line 108, a plurality of electrostatic discharge circuits 109, and a plurality of gate lines 110. Here, the static electricity line 108, the plurality of electrostatic discharge circuits 109, and the plurality of gate lines 110 are all located between the organic photodetection function layer 1022 and the base substrate 101. The electrostatic wiring 108 is electrically connected with the gate lines 110 through the electrostatic discharge circuits 109.

In some embodiments, in the detection substrate provided by the embodiments of the disclosure, as shown in FIG. 7, the electrostatic discharge circuits 109 are electrically connected with the gate lines 110 in one-to-one correspondence so as to release the static electricity accumulated on each gate line 110 in time.

In some embodiments, in the detection substrate provided by the embodiments of the disclosure, as shown in FIG. 7 and FIG. 8, the electrostatic discharge circuit 109 includes a first transistor T1 and a second transistor T2; where the gate of the first transistor T1 is electrically connected with the gate line 110, the first electrode of the first transistor T1 is electrically connected with the gate of the first transistor T1, the second electrode of the first transistor T1 is electrically connected with the first electrode of the second transistor T2; the gate of the second transistor T2 is electrically connected with the static electricity line 108, the first electrode of the second transistor T2 is electrically connected with the gate of the second transistor T2, and the second electrode of the second transistor T2 is electrically connected with the first electrode of the first transistor T1. In specific implementation, when there is a lot of static electricity accumulated on the gate line 110, the first transistor T1 is turned on under the electrostatic action, so that the static electricity is transmitted to the second transistor T2 through the first transistor T1; the second transistor T2 is turned on under the electrostatic action, so that the static electricity is transmitted to the static electricity line 108 through the second transistor T2 for discharge.

It should be noted that the first transistor T1 and the second transistor T2 may be top-gate transistors or bottom-gate transistors, which are not limited herein. In some embodiments, the first transistor T1 and the second transistor T2 are low-temperature polysilicon transistors, but in some embodiments, the first transistor T1 and the second transistor T2 can also be amorphous silicon transistors, oxide transistors, field effect transistors and the like. In addition, the first electrode and the second electrode of the first transistor T1 and the second transistor T2 are respectively a drain and a source, which are not specifically distinguished here.

In some embodiments, the detection substrate provided by the embodiments of the disclosure, as shown in FIG. 8, may further include a plurality of bridge lines 111, and a layer where the bridge lines 111 are, are located between the layer where the first electrode 1021 is and the layer where the electrostatic discharge circuit 109 is. A part of the bridge lines 111 connect the gate of the first transistor T1 and the first electrode of the first transistor T1, and the rest of the bridge lines 111 connect the gate of the second transistor T2, the first electrode of the second transistor T2 and the static electricity line 108. Usually, the gate line 110 is in a layer same as a layer where the gate of the transistor is. The gate line 110 and the gate of the transistor are in a same layer and of a same material. The static electricity line 108 and the first and second electrodes of the transistor are in a same layer and of a same material. The gate insulating layer 112 between the active layer and the gate of the transistor is formed as an entire surface, so that the gate of the second transistor T2 is isolated from the static electricity line 108 through the gate insulating layer 112, and the first electrode of the first transistor T1 is isolated from the gate line 110 through the gate insulating layer 112. In order to realize the electrical connection among the gate of the second transistor T2 and the first electrode of the second transistor T2 and the static electricity line 108, and the electrical connection between the gate of the first transistor T1 and the first electrode of the first transistor T1, the same mask may be adopted to drill holes in the second insulating layer 107 and the gate insulating layer 112, and the bridge line 111 may be formed while forming the second bias portion 1032, so that the electrically connection among the gate of the second transistor T2, the second gate of the second transistor T2, and the electrostatic wiring 108, and the electrically connection between the gate of the first transistor T1 and the first electrode of the first transistor T₁ can be achieved respectively through different bridge lines 111.

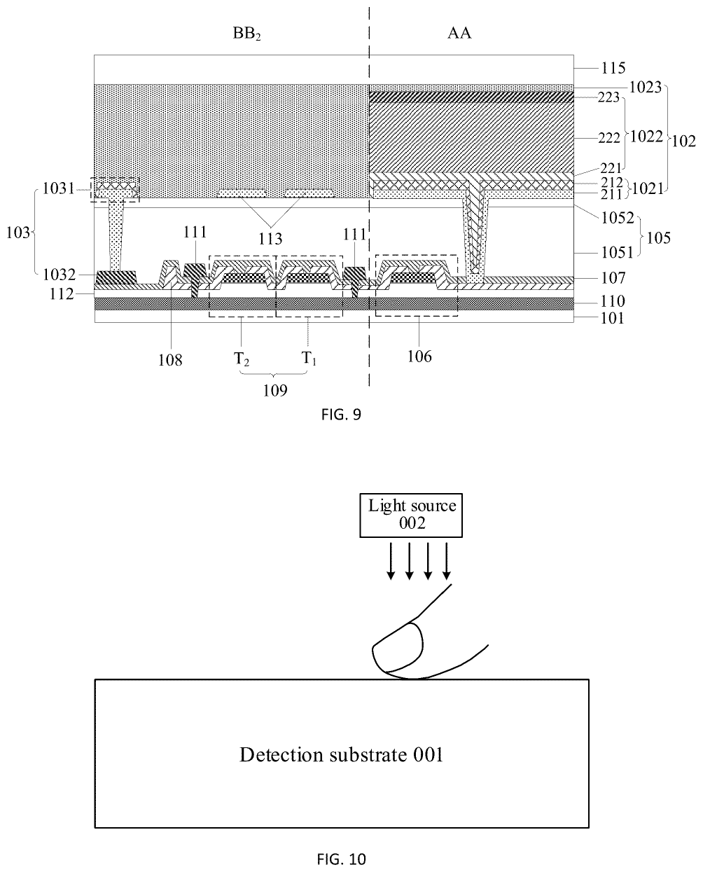

In some embodiments, the detection substrate provided by the embodiments of the disclosure, as shown in FIG. 9, may further include a plurality of light-shielding elements 113 located in the peripheral area BB. The layer where the plurality of light-shielding elements 113 are is located between the organic photodetection function layer 1022 and the base substrate 101. The orthographic projections of the plurality of light-shielding elements 113 on the base substrate 101 overlap the orthographic projection of the active layer of each first transistor T1 on the base substrate 101, and the orthographic projection of the active layer of each second transistor T2 on the base substrate 101. In this way, light can be shielded by the light-shielding element 113 to prevent light from irradiating the active layer and causing electric leakage.

In some embodiments, in the detection substrate provided by the embodiments of the disclosure, the plurality of light-shielding elements 113 and the metal part 211 can be arranged in the same layer and of the same material, so as to save mask process, improve production efficiency and reduce production cost.

In some embodiments, in the detection substrate provided by the embodiments of the disclosure, as shown in FIG. 2 and FIG. 7, the peripheral area BB may further include a third peripheral area BB3. The third peripheral area BB3 connects the first peripheral area BB1 and the second peripheral area BB2. A plurality of gate lines 110 are located in the photosensitive area AA. The static electricity line 108 is located in the first peripheral area BB1, the second peripheral area BB2 and the third peripheral area BB3. The static electricity line 108 in the second peripheral area BB2 is located between the bias line 103 and the photosensitive area AA. A plurality of electrostatic discharge circuits 109 are located in the first peripheral area BB1 and the second peripheral area BB2, and the plurality of electrostatic discharge circuits 109 are located between the static electricity line 108 and the photosensitive area AA. The gate driver chip 104 is located on a side of the static electricity line 108 away from the photosensitive area AA, and the gate driver chip 104 is electrically connected with the gate line 110 to provide the scan signal to the gate line 110.

In some embodiments, in the detection substrate provided by the embodiments of the disclosure, as shown in FIG. 2, the peripheral area BB may further include a fourth peripheral area BB4. The fourth peripheral area BB4 is opposite to the third peripheral area BB3. The detection substrate may further include a readout chip (ROIC COF) 114 bonded to the fourth peripheral area BB4, and the readout chip 114 is electrically connected with the bias line 103.

In some embodiments, as shown in FIG. 3, FIG. 4, FIG. 7 and FIG. 8, the detection substrate may further include a protective film 115 and the like on the side of the second electrode 1023 away from the base substrate 101. Other essential components in the detection substrate should be understood by those of ordinary skill in the art, and will not be repeated here, and should not be used as limitations to the disclosure.

Based on the same inventive concept, an embodiment of the disclosure provides a detection device, as shown in FIG. 10, including a detection substrate 001 and a light source 002, where the detection substrate 001 is the above-mentioned detection substrate 001 provided by the embodiment of the disclosure. In some embodiments, the light source 002 is a light-emitting diode (LED) that emits infrared light. The light-emitting diode can be positioned directly above the finger or on both sides of the finger, so that after the finger presses the detection substrate 001, the infrared light emitted by the light-emitting diode is transmitted through the finger. After passing through the finger vein, it is received by the detection substrate 001, and then the image of the finger vein is obtained. Since the problem-solving principle of the detection device is similar to the problem-solving principle of the above-mentioned detection substrate, the implementation of the detection device provided by the embodiment of the disclosure can refer to the implementation of the above-mentioned detection substrate provided by the embodiment of the disclosure, and will not be repeated.

Obviously, those skilled in the art can make various changes and modifications to the embodiments of the disclosure without departing from the spirit and scope of the embodiments of the disclosure. In this way, if these modifications and variations of the embodiments of the disclosure fall within the scope of the claims of the disclosure and their equivalent technologies, the disclosure also intends to include these modifications and

[symbol]

1. A detection substrate, comprising:
a base substrate comprising a photosensitive area, and a peripheral area surrounding the photosensitive area;
a plurality of organic photodetectors on the base substrate, wherein the plurality of organic photodetectors are arranged in an array in the photosensitive area, and each of the organic photodetectors comprises a first electrode, an organic photodetection function layer and a second electrode which are arranged in a stack manner, wherein second electrodes of all the organic photodetectors are formed as an integrated second electrode and extend from the photosensitive area to the peripheral area;
a bias line, wherein the bias line is a strip-shaped line extending along a first direction in the peripheral area, and is electrically connected with the second electrodes in the peripheral area; and
a minimum distance between the bias line and the organic photodetection function layer in a second direction is greater than a preset threshold;
wherein the first direction and the second direction are perpendicular to each other, and the first direction and the second direction are both parallel to the base substrate.

2. The detection substrate according to claim 1, wherein
the peripheral area comprises a first peripheral area and a second peripheral area, wherein the first peripheral area is configured to bond a gate driver chip, and the second peripheral area is opposite to the first peripheral area; and
the integrated second electrodes extends from the photosensitive area to the second peripheral area, and the bias line is located in the second peripheral area.

3. The detection substrate according to claim 1, wherein an orthographic projection of a boundary of the bias line at a side away from the photosensitive area on the base substrate is approximately coincident with an orthographic projection of a boundary of the integrated second electrode on the base substrate are approximately coincident.

4. The detection substrate according to claim 1, wherein the bias line comprises:
a first bias portion, wherein the first bias portion and the first electrode are in a same layer and of same material, and the first bias portion is in direct contact with the integrated second electrodes;
a second bias portion, wherein the second bias portion is located between a layer where the first electrode is and the base substrate, and the second bias portion is electrically connected with the first bias portion.

5. (canceled)

6. The detection substrate according to claim 45, further comprising a first insulating layer, wherein the first insulating layer is located between the layer where the first electrode is and the base substrate;
the first insulating layer comprises a first via hole, and an orthographic projection of the first via hole on the base substrate is located within an orthographic projection of the bias line on the base substrate; and
the first bias portion and the second bias portion are electrically connected through the first via hole.

7. The detection substrate according to claim 6, further comprising: a pixel driving circuit and a second insulating layer;
wherein the pixel driving circuit is located between a layer where the second bias portion is and the base substrate, and the second insulating layer is located between the layer where the second bias portion is and a layer where the pixel driving circuit is;
the first insulating layer and the second insulating layer comprise a second via hole passing through the first insulating layer and the second insulating layer, and an orthographic projection of the second via hole on the substrate is located within an orthographic projection of the organic photodetector on the base substrate;
the pixel driving circuit is electrically connected with the organic photodetector through the second via hole.

8. The detection substrate according to claim 1,
wherein the bias line comprises a plurality of first sub-bias lines and a plurality of second sub-bias lines, the plurality of first sub-bias lines and the plurality of second sub-bias lines are arranged in a same layer and intersect with each other;
wherein the first sub-bias lines extend along the first direction, and the second sub-bias lines extend along the second direction.

9. The detection substrate according to claim 8, wherein a line width of the first sub-bias lines is smaller than a line width of the second sub-bias lines; and/or
the second sub-bias line comprises at least one hollow pattern, and an orthographic projection of the at least one hollow pattern on the base substrate and orthographic projections of the first sub-bias lines on the base substrate do not overlap each other.

10. (canceled)

11. The detection substrate according to claim 8, wherein a length of the second sub-bias line in the second direction is greater than or equal to 650 μm and less than or equal to 850 μm.

12. The detection substrate according to claim 1, wherein a minimum distance between the bias line and the organic photodetection function layer in the second direction is greater than or equal to 500 μm and less than or equal to 600 μm.

13. The detection substrate according to claim 2, further comprising a static electricity line, a plurality of electrostatic discharge circuits, and a plurality of gate lines located in the peripheral area, wherein
the static electricity line, the plurality of electrostatic discharge circuits, and the plurality of gate lines are all located between the organic photodetection function layer and the base substrate, and the static electricity line is electrically connected with the gate line through the electrostatic discharge circuit;
the plurality of electrostatic discharge circuits are electrically connected with the plurality of gate lines in a one-to-one correspondence.

14. (canceled)

15. The detection substrate according to claim 13, wherein the electrostatic discharge circuit comprises a first transistor and a second transistor; wherein
a gate of the first transistor is electrically connected with the gate line, a first electrode of the first transistor is electrically connected with the gate of the first transistor, and a second electrode of the first transistor is electrically connected with a first electrode of the second transistor;
a gate of the second transistor is electrically connected with the static electricity line, the first electrode of the second transistor is electrically connected with the gate of the second transistor, and a second electrode of the second transistor is electrically connected with the first electrode of the first transistor.

16. The detection substrate according to claim 15, further comprising a plurality of bridge lines, wherein
a layer where the plurality of bridge lines are located is located between the layer where the first electrode is and the base substrate, a part of the plurality of bridge lines connect the gate of the first transistor and the first electrode of the first transistor, and a rest of the plurality of bridge lines connect the gate of the second transistor, the first electrode of the second transistor and the static electricity line.

17. The detection substrate according to claim 15, further comprising a plurality of light-shielding elements located in the peripheral area, wherein a layer where the plurality of light-shielding elements are is located between the organic photodetection function layer and the base substrate;
orthographic projections of the plurality of light-shielding elements on the base substrate overlap with an orthographic projection of an active layer of each of the first transistors on the base substrate, and an orthographic projection of an active layer of each of the second transistors on the base substrate.

18. The detection substrate according to claim 17, wherein the first electrode comprises a metal part, and the plurality of light-shielding elements and the metal part are arranged in a same layer, and of same material.

19. The detection substrate according to claim 18, wherein the first electrode further comprises a transparent conductive part, the transparent conductive part is located on a side of the metal part away from the base substrate, and the transparent conductive part is in direct contact with the metal part.

20. The detection substrate according to claim 13, wherein the peripheral area further comprises a third peripheral area, and the third peripheral area connects the first peripheral area and the second peripheral area;
the plurality of gate lines are located in a light-emitting area photosensitive area;
the static electricity line is located in the first peripheral area, the second peripheral area, and the third peripheral area, and the static electricity line in the second peripheral area is located between the bias line and the light emitting area photosensitive area;
the plurality of electrostatic discharge circuits are located in the first peripheral area and the second peripheral area, and the plurality of electrostatic discharge circuits are located between the static electricity line and the light emitting area photosensitive area.

21. The detection substrate according to claim 20, wherein the gate driving chip is located on a side of the static electricity line away from the photosensitive area, and the gate driving chip is electrically connected with the gate lines.

22. The detection substrate according to claim 19, wherein the peripheral area further comprises a fourth peripheral area, and the fourth peripheral area is opposite to the third peripheral area;
the detection substrate further comprises a readout chip, the readout chip is bonded onto the fourth peripheral area, and the readout chip is electrically connected with the bias line.

23. A detection device, comprising a light source and the detection substrate according to claim 1.
